(19) United States
(12) Patent Application Publication
(10) Pub. No.: US 2025/0244363 A1
(43) Pub. Date: Jul. 31, 2025

(54) SYSTEM AND METHOD FOR IMPROVED SIGNAL TRIGGERING IN SPECTRUM ANALYZERS

(71) Applicant: Keysight Technologies, Inc., Santa Rosa, CA (US)

(72) Inventors: Allen Montijo, Colorado Springs, CO (US); Ryan Pearson, Colorado Springs, CO (US)

(21) Appl. No.: 18/428,382

(22) Filed: Jan. 31, 2024

(51) Int. Cl. G01R 13/32; G01R 13/22

(52) U.S. Cl. CPC G01R 13/32; G01R 13/225

(57) ABSTRACT

A spectrum analyzer triggering system includes a frequency select trigger (FST) configured to generate a power signal from an input digital signal, the input power signal including high or low transitions at given transmission intervals of the input digital signal. The triggering system further includes a hysteresis comparator configured to generate a trigger pulse at the high or low transitions of the input power signal, and a leaky peak detector (LPD) configured to inhibit errant high or low transitions of the input power signal from causing the hysteresis comparator to generate a trigger pulse.

### FIELD OF INVENTION

The present disclosure generally relates to systems and methods for improving signal triggering in spectrum analyzers and the like using a Leaky Peak Detector (LPD).

### BACKGROUND

Digital storage oscilloscopes (DSOs) and spectrum analyzers are widely used in various fields such as electronics, telecommunications, and signal processing. These devices are designed to capture, process, and display waveform signals in a digital format. They convert the analog signals into digital form using an analog-to-digital converter (ADC), and then process the digitized signals to extract useful information.

One of the main components of a spectrum analyzer is the analog-to-digital converter (ADC). The ADC is responsible for converting the analog input signal into a series of digital words or symbols. This conversion process is a core component of digital storage oscilloscopes (DSOs) as well. The ADC block is typically designed to utilize the full dynamic range to obtain the maximum resolution and accurate measurements.

Another integral part of a spectrum analyzer is the triggering system. The triggering system establishes a point in time on the input signal upon which to establish a synchronized acquisition. This is particularly useful when analyzing signals that have varying voltage and power levels, such as data transmissions. The trigger system allows the user to capture specific events or changes in the signal, such as the start of a transmission.

Furthermore, spectrum analyzers often employ a variety of signal conditioning processes to scale the waveform correctly within the dynamic range of the ADC and the amplifier. These processes include attenuation, DC offset, and variable gain amplification.

### SUMMARY

In some aspects of the inventive concepts, a spectrum analyzer triggering system is provided that includes a frequency select trigger (FST) configured to generate a power signal from an input digital signal, the input power signal having high or low levels at given transmission intervals of the input digital signal. The triggering system further includes a hysteresis comparator configured to generate a trigger pulse at rising or falling edges of the input power signal, and a leaky peak detector (LPD) configured to inhibit errant rising or falling edges of the input power signal from causing the hysteresis comparator to generate a trigger pulse.

The digital signal may be a complex IQ signal, and the power signal may be generated having a magnitude I²+Q².

The LPD may include a comparator configured to compare the input power signal with a current decayed value, a multiplexer, under control of the comparator, configured to output one of the input power signal and the current decayed value as a trigger signal; and a memory unit configured to store the trigger signal for use in a subsequent operation to determine a next decayed value. The multiplexer may output a greater of the input power signal and the current decayed value as the trigger signal. Alternatively, the multiplexer outputs a lesser of the input power signal and the current decayed value as the trigger signal. The LPD may further comprises a multiplier configured to multiply the trigger signal stored in the memory unit and a decay factor to obtain the next decayed value. The decay value may be stored in a register, and may be programmable.

The input power signal may be supplied at a rate of one sample per clock, and the LPD may process the input power signal at a rate of one sample per clock.

In other aspects of the inventive concepts, a polyphase peak detector is provided that includes a memory element and a plurality of leaky peak detectors (LPDs) connected in a daisy chain, the plurality of leaky peak detectors including a first LPD of the daisy chain and a last LPD of the daisy chain, each LPD receiving an input power signal of M samples per clock, where M is a plural integer. Each LPD is configured, during each clock, to compare a respective sample of the input power signal with a decayed value, and to output a selected one of the input power signal and the decayed value as a trigger signal. Except for the last LPD of the daisy chain, the decayed value of each LPD of the daisy chain is forwarded to each next LPD of the daisy chain for processing. The last LPD of the daisy chain forwards its decayed value to the memory element for storage therein, and the first LPD of the daisy chain receives the decayed value stored in the memory element.

The decayed value of a given clock in each LPD may be obtained by applying a decay factor to the trigger signal of a previous clock. The decay value may be stored in a register, and may be programmable.

The input power signal may be derived from a complex IQ signal.

The trigger signals of the LPDs may be forwarded to an edge detection circuit with hysteresis for triggering.

### BRIEF DESCRIPTION OF DRAWINGS

The above and other aspects and features of the inventive concepts will become readily apparent from the detailed description that follows, with reference to the accompanying drawings, in which:

FIG. 1 is a block diagram of an exemplary digital storage oscilloscope (DSO);

FIG. 2 is a circuit diagram illustrating an example of the analog input signal conditioning circuit shown in FIG. 1;

FIG. 3 is a circuit diagram for reference in describing the ADC and the trigger block shown in FIG. 1;

FIG. 4 is a circuit diagram for reference in describing examples of the acquisition memory and the timebase system shown in FIG. 1;

FIG. 5 is a block diagram for reference in describing the DSP display block of FIG. 1;

FIG. 6 is a block diagram of an oscilloscope signal acquisition and processing system;

FIG. 7 is a block diagram of an exemplary signal analyzer;

FIG. 8 generally shows a block circuit diagram for reference in describing down-sampling of the output of the ADC;

FIG. 9 is a circuit diagram for reference in describing a leaky peak detector (LPD) according to at least one embodiment of the inventive concepts;

FIG. 10 is a signal diagram for reference in describing the operation of the LPD and hysteresis comparator of FIG. 9 according to at least one embodiment of the inventive concepts; and

FIG. 11 is a block circuit diagram of a polyphase peak detector according to at least one embodiment of the inventive concepts.

### DETAILED DESCRIPTION

In the following detailed description, for purposes of explanation and not limitation, representative embodiments disclosing specific details are set forth in order to provide a thorough understanding of the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparatuses and methods may be omitted to avoid obscuring the description of the example embodiments. Such methods and apparatuses are clearly within the scope of the present teachings. Further, throughout the drawings, like reference numbers refer to the same or similar elements.

The terminology used herein is for purposes of describing particular embodiments only, and is not intended to be limiting. The defined terms are in addition to the technical and scientific meanings of the defined terms as commonly understood and accepted in the technical field of the present teachings. As used in the specification and appended claims, the terms ‘a’, ‘an’ and ‘the’ include both singular and plural referents, unless the context clearly dictates otherwise. Thus, for example, ‘a device’ includes one device and plural devices. Further, for example, when one element is described as being “connected to” another element, the one element may be directly connected to the other element, or indirectly connected to the other element in an operative manner.

Separately, as is traditional in the field of the inventive concepts, example embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, and the like, which may be formed using semiconductor-based fabrication techniques or other manufacturing technologies. In the case of the blocks, in the absence of an indication to the contrary, the units and/or modules being implemented by microprocessors or similar may be programmed using software (e.g., microcode) to perform various functions discussed herein and may optionally be driven by firmware and/or software. Alternatively, each block, unit and/or module may be implemented by dedicated hardware, or as a combination of dedicated hardware to perform some functions and a processor (e.g., one or more programmed microprocessors and associated circuitry) to perform other functions. Also, each block, unit and/or module of the example embodiments may be physically separated into two or more interacting and discrete blocks, units and/or modules without departing from the scope of the example embodiments. Conversely, the blocks, units and/or modules of the example embodiments may be physically combined into more complex blocks, units and/or modules without departing from the scope of the example embodiments.

For context, spectrum analyzers are often used to measure data transmissions that have varying voltage and power levels when transitioning between different symbols. This means it is not uncommon for the voltage of such a transmission to have occasional errant power transitions and otherwise remain low throughout the message. It is often desirable to only trigger on and acquire the beginning of such a transmission rather than the middle portion, but this can be difficult due to the voltage and power differences between different symbols referenced above, as they often appear similar to the beginning of a transmission.

A so-called Frequency Select Trigger (FST) allows triggering on the rising or falling edge of a power signal. The FST may correctly trigger on and allow capture of the start of transmissions, but it can also result in lots of errant triggers around interim high power transitions. These undesired triggers can block the acquisition system from acquiring desired trigger events, resulting in loss of useful data. Even if the desired event is found, lots of undesired triggers must be eliminated in post processing to make the data useful.

As described herein, the inventive concepts are directed to the addition of a Leaky Peak Detector (LPD) to, for example, the existing FST in high end digital oscilloscopes and spectrum analyzers. The LPD allows a time factor to be included in the triggering process. This in turn allows the user to calibrate the time factor such that they can throw out the errant power transitions during a transmission and only consider the start of such a transmission. The LPD is an improvement over FST alone because it allows a time decay factor to be introduced. This time factor can be used to prevent many of the undesired triggers that could otherwise occur and ensure the data of interest is always able to be acquired.

The LPD circuit of at least some embodiments has a relatively simple circuit structure and operates at relatively high speeds. This is because the LPD uses a simple comparator to select the maximum between the input signal and its own memory. No complex integration is required. Further savings are achieved when the circuit is implemented in a polyphase design. While a slower, larger integrator might reduce the number of possible phases in the design, a simple comparator circuit allows more phases and hence more time resolution on the trigger output.

In some embodiments, the LPD operates on a power signal. When analyzing voltage there is an inherent phase dependence on the signal, a sinusoid will only go from below to above a threshold at a certain phase. This is not true for the power of the signal, i.e., the rise in power at the start of a transmission will be visible at the same relative time regardless of the phase of the signal. The use of the power of the signal not only removes the phase dependence, but also allows complex single-sided filtering operations to be performed. This filtering can be used to isolate spectral regions of interest.

As will be explained later herein, the LPD of some embodiments works by taking an input power signal and comparing it to a decayed value stored in memory. The rate of decay is programmable. It then selects whichever value between the two is larger and forwards it along to be used as the trigger signal and the next “remembered” signal.

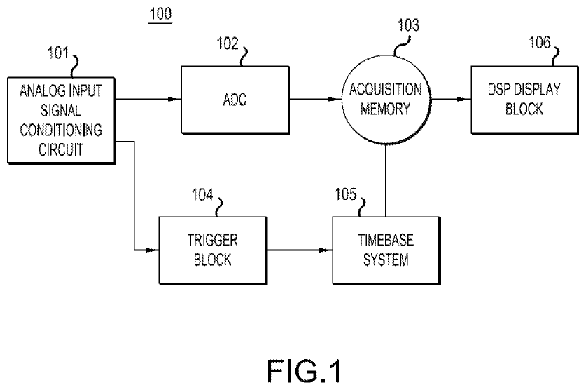

Prior to discussing in detail further aspects of the inventive concepts, as background a digital oscilloscope and spectrum analyzer will be described with reference to FIGS. 1-7.

Referring to FIG. 1, a digital storage oscilloscope (DSO) 100 is depicted. The DSO 100 is a type of signal processing device that is used to capture, process, and display waveform signals in a digital format. The DSO 100 includes various components that are interconnected to illustrate the path taken by an analog signal from input to display.

The analog signal first enters the DSO 100 through an analog input signal conditioning circuit 101. The analog input signal conditioning circuit 101 is configured to condition the analog signal before it is processed by the DSO 100. This may involve adjusting the amplitude, offset, frequency content or phase of the analog signal to ensure that it is within the acceptable range for the DSO 100.

After being conditioned, the analog signal is then fed into an analog-to-digital converter (ADC) 102. The ADC 102 is responsible for converting the analog signal into a digital format. This involves sampling the analog signal at regular intervals and quantizing each sample to produce a digital representation of the analog signal.

The digitized signal is then stored in an acquisition memory 103. The acquisition memory 103 serves as a temporary storage area for the digitized signal. It allows the DSO 100 to store the digitized signal for later processing and analysis.

Simultaneously, the digitized signal is also passed to a trigger block 104. The trigger block 104 interacts with a timebase system 105 to coordinate the timing of the signal processing operations performed by the DSO 100. The trigger block 104 can be configured to generate a trigger signal based on a specific event or condition in the digitized signal. This trigger signal can then be used to synchronize the processing of the digitized signal with other operations of the DSO 100.

Finally, the processed digitized signal is sent to a digital signal processor (DSP) display block 106 for visualization. The DSP display block 106 is responsible for generating a visual representation of the digitized signal. This visual representation can be displayed on a monitor or other display device, allowing users to analyze the characteristics of the digitized signal.

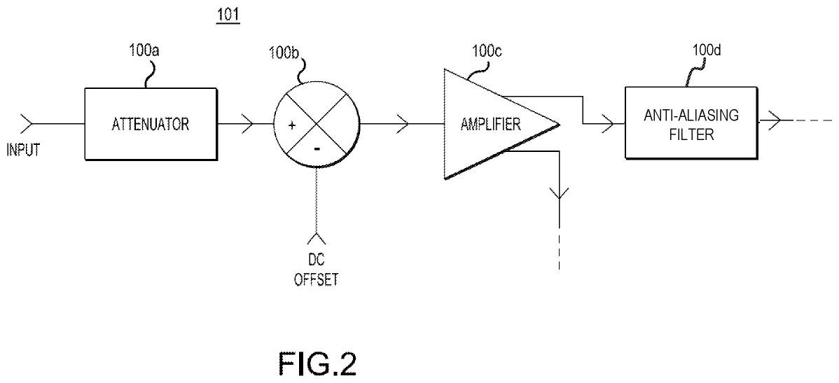

Referring to FIG. 2, an example of the analog input signal conditioning circuit 101 of FIG. 1 is illustrated. In this example, the analog input signal conditioning circuit 101 includes an attenuator 100a, a DC offset 100b, an amplifier 100c, and an anti-aliasing filter 100d. The attenuator 100a is used to reduce the amplitude of the incoming signal to a level that can be handled by the subsequent stages of the DSO 100. The DC offset 100b is used to shift the signal up or down in voltage, which can be useful for centering the signal around a particular voltage level. The amplifier 100c is used to increase the amplitude of the signal, which can be useful for boosting weak signals to a level that can be effectively processed by the DSO 100. The anti-aliasing filter 100d is a lowpass filter utilized to ensure the signal is bandlimited prior to sampling.

In some cases, the analog input signal conditioning circuit 101 may be configured to perform additional signal processing operations, such as filtering or modulation. These additional operations can be used to further condition the analog signal, enhancing the performance and functionality of the DSO 100.

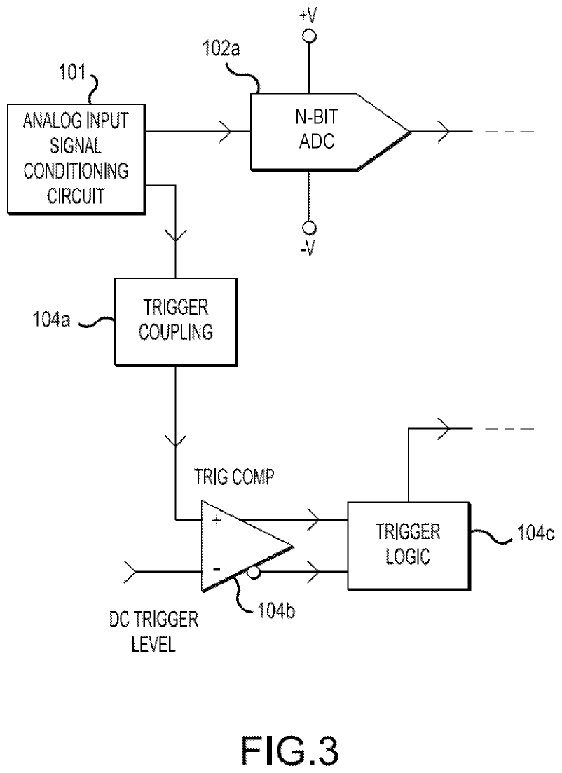

Referring to FIG. 3, a circuit diagram is provided to describe the analog-to-digital converter (ADC) 102 and the trigger block 104 shown in FIG. 1. As previously mentioned, the ADC 102 is responsible for converting the analog signal into a digital format. This conversion process involves sampling the analog signal at regular intervals and quantizing each sample to produce a digital representation of the analog signal. In this example, the ADC 102 is an N-bit analog-to-digital converter, which means it can represent the analog signal with a resolution of 2^{N} distinct levels.

The trigger block 104 of the illustrated example includes a trigger coupling 104a, a trigger comparator 104b, and a trigger logic 104c. The trigger coupling 104a is used to access the analog input signal. The trigger comparator 104b is used to compare the input

signal with a reference signal to determine when a trigger event has occurred. The trigger logic 104c is used to generate the trigger signal based on the output of the trigger comparator 104b.

In some cases, the mark (trigger signal) position may be used to align data when plotting triggered data from multiple sources. This involves using the mark position as a reference point in calculations to determine when to start plotting the data. This can be useful for aligning the data with other signals or events, or for synchronizing the data with the operation of other components of the DSO 100.

In other cases, the mark position may be used to determine the location of the marked sample within the reduced set of samples output from the decimation circuit. This involves using the mark position as a reference point to identify the marked sample within the output data pipe. This can be useful for tracking the marked sample as it moves through the DSO 100, or for identifying the marked sample for further processing or analysis.

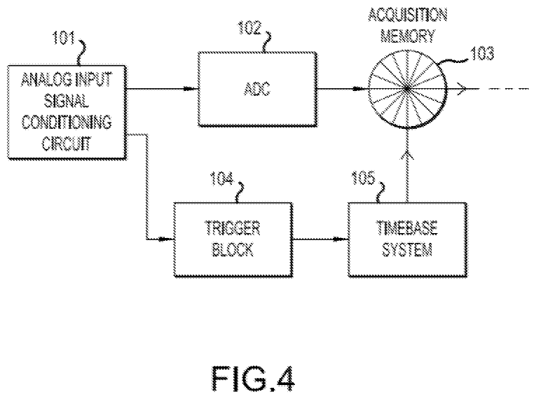

Referring to FIG. 4, a block diagram is provided to describe examples of the acquisition memory 103 and the timebase system 105. As previously mentioned, the acquisition memory 103 is a component of the digital storage oscilloscope (DSO) 100, which serves as a temporary storage area for the digitized signal. The acquisition memory 103 allows the DSO 100 to store the digitized signal for later processing and analysis. The size of the acquisition memory 103 can vary depending on the specific requirements of the DSO 100. In some cases, the acquisition memory 103 may be large enough to store a large number (i.e., millions to billions) of samples, allowing for more detailed analysis of the signal. In other cases, the acquisition memory 103 may be smaller, allowing for faster processing of the signal.

The timebase system 105 is another component of the DSO 100, which interacts with the trigger block 104 to coordinate the timing of the signal processing operations performed by the DSO 100. That is, the timebase system 105 controls the acquisition to store a requested number of samples before the marked sample and after it. It may also store metadata to be used for the signal processing operations. The timebase system 105 can be configured to generate a timing signal based on a specific event or condition in the digitized signal. This timing signal can then be used to synchronize the processing of the digitized signal with other operations of the DSO 100. The timebase system 105 may also be configured to adjust a decimation process such that a lower sampling rate is stored.

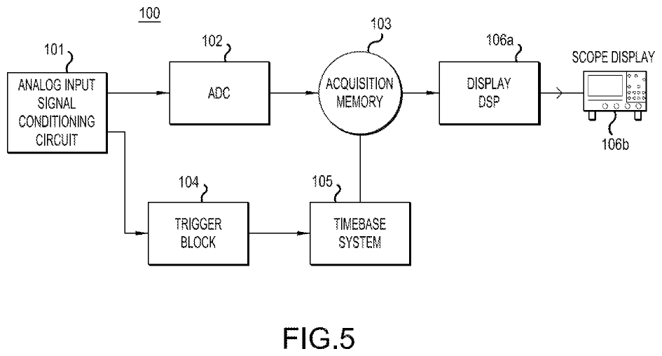

FIG. 5 is a block diagram for reference in describing the digital signal processor (DSP) display block 106 of the digital storage oscilloscope (DSO) 100. The DSP display block 106 is responsible for generating a visual representation of the digitized signal. This visual representation can be displayed on a monitor or other display device, allowing users to analyze the characteristics of the digitized signal.

The DSP display block 106 includes a display 106b and a display digital signal processor (DSP) 106a. The display 106b is the interface through which the visual representation of the digitized signal is presented to the user. The display digital signal processor (DSP) 106a is responsible for processing the digitized signal and generating the visual representation that is displayed on the display 106b.

The DSP display block 106 interacts with the timebase system 105, the acquisition memory 103, the analog-to-digital converter (ADC) 102, the analog input signal conditioning circuit 101, and the trigger block 104. The timebase system 105 coordinates the timing of the signal processing operations performed by the DSO 100. The acquisition memory 103 serves as a temporary storage area for the digitized signal. The ADC 102 converts the analog signal into a digital format. The analog input signal conditioning circuit 101 conditions the analog signal before it is processed by the DSO 100. The trigger block 104 generates a trigger signal based on a specific event or condition in the digitized signal.

In some cases, the mark position may be used to facilitate plotting operations of the signal processing device. This involves using the mark position as a point in calculations to determine which data in the memory 103 is to be processed and plotted. This can be useful for aligning the data with other signals or events, or for synchronizing the data with the operation of other components of the DSO 100. For example, the mark position can be used to align trigger when plotting triggered data from multiple sources, or to correct a phase offset introduced during signal acquisition.

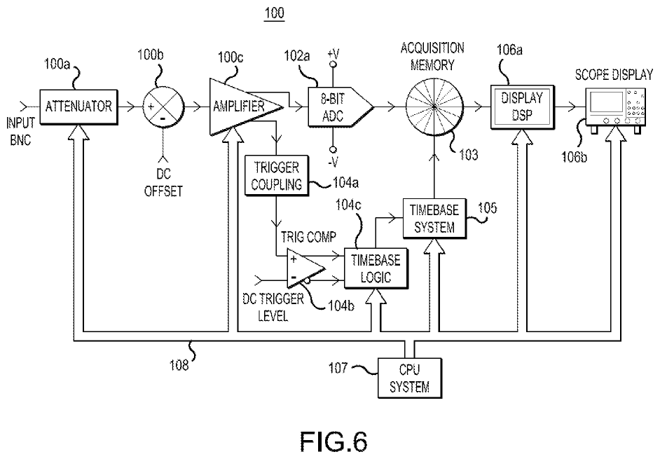

FIG. 6 is an overall block diagram of the digital storage oscilloscope 100 including the components described above in connection with FIGS. 2-5. In addition, FIG. 6 depicts a CPU system 107 which coordinates and directs operations of the various components, as well as a bus system 108 over which the various components may communicate with one another.

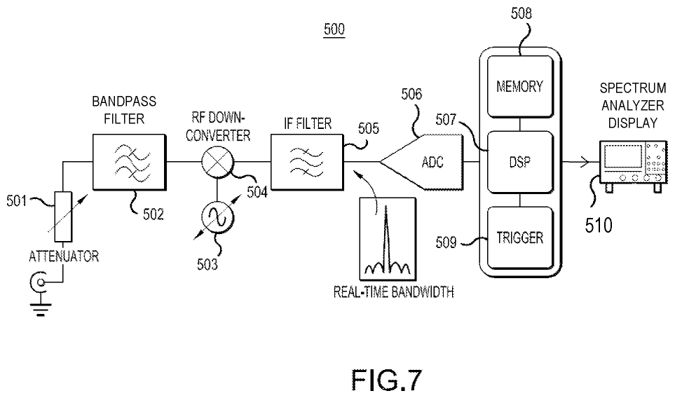

Referring to FIG. 7, a block diagram illustrating an exemplary signal analyzer 500. As shown, the signal analyzer 500 includes an attenuator 501 that receives an input signal. The attenuator 501 is used to reduce the amplitude of the incoming signal to a level that can be handled by the subsequent stages of the signal analyzer. The attenuated signal is then fed into a bandpass filter 502. The bandpass filter 502 is used to remove undesired frequency components from the signal, thereby smoothing out the signal and reducing noise.

After being filtered, the signal is then passed to a mixer 504. The mixer 504 also receives a signal from a local oscillator (LO) 503. The LO 503 generates a signal with a constant frequency that is used to mix with the filtered signal. The mixed signal is then processed by a frequency mixer 504. The frequency mixer 504 combines the filtered signal and the signal from the LO 503 to produce a mixed signal with an intermediate frequency that is the difference in the frequencies of the two input signals.

The mixed signal is then passed through an intermediate frequency (IF) filter 505. The IF filter 505 is used to further filter the mixed signal, removing unwanted frequency components and leaving a desired frequency band. The filtered mixed signal is then converted into a digital format by an analog-to-digital converter (ADC) 506. The ADC 506 samples the filtered mixed signal at regular intervals and quantizes each sample to produce a digital representation of the signal.

The digitized signal is then processed by a digital signal processor (DSP) 507. The DSP 507 performs various signal processing operations on the digitized signal, such as filtering, decimation, and compression. The processed digitized signal is then stored in an acquisition memory 508 for later retrieval and analysis.

The signal processing device also includes trigger circuits 509 that generate a trigger signal based on a specific event or condition in the digitized signal. This trigger signal can be used to synchronize the processing of the digitized signal with other operations of the signal processing device. For example, the trigger signal can be used to correct a phase offset introduced during signal acquisition.

The processed digitized signal is then displayed in various formats on a spectrum analyzer display 510. These formats may include, as examples, a frequency domain view and a spectrogram view. Each of these views provides a different perspective on the signal, allowing users to analyze the signal in various ways.

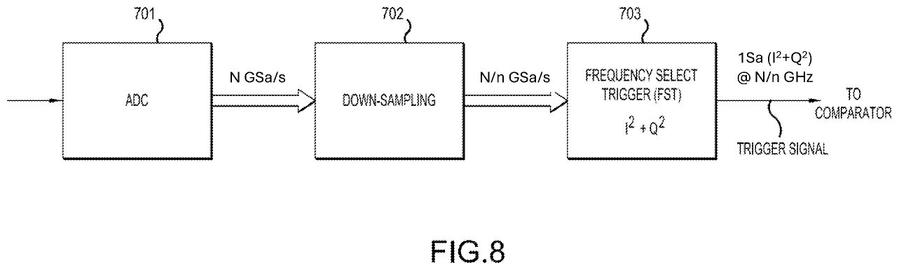

FIG. 8 is a block diagram for reference in describing the analog-to-digital converter (ADC) 701, down-sampling circuits 702, and frequency select trigger (FST) 703 that may be contained in a spectrum analyzer such as the spectrum analyzer 500 of FIG. 7.

As previously discussed, the ADC 701 is responsible for converting the conditioned analog input signal into a series of digital words (also referred to as samples). This conversion process is a core component of the spectrum analyzer. The ADC 701 is typically designed to utilize the full dynamic range to obtain the maximum resolution and accurate measurements. In some operational variations, the ADC 701 is configured to receive a wideband signal and generate the power signal based on a selected bandwidth of the wideband signal.

The down-sampling circuits 702, which may contain filters that reduce the signal's bandwidth, are components of the spectrum analyzer 500 that operate to reduce the sampling rate of the digital words output by the ADC 701. This is particularly useful when the ADC 701 outputs digital words at a high sampling rate, and it is desired to process the digital words at a lower sampling rate for further processing and display. In FIG. 8, a divide-by-n down-sampling takes place in which an N GSa/s output from the ADC 701 is down-sampled to an N/n GSa/s signal by the down-sampling circuits 702. As one non-limiting example, N may be 64 and n may be 16, such that 4 GSa/s is output from the down-sampling circuits 702. The down-sampling circuits 702 achieve this by bandpass filtering and discarding some of the digital words output by the ADC 701, thereby reducing the sampling rate of the digital words that are passed on for further processing.

The FST 703 is a component of the spectrum analyzer 500 that generates power signal samples from the digital words output by the ADC 701. The FST 703 operates to calculate the power of the signal, represented as I²+Q², for each of the digital words output by the down-sampling circuits 702. The power signal samples generated by the FST 703 provide a measure of the power of the signal within the selected bandwidth of the wideband signal received by the ADC 701. The power signal samples are then used for further processing and display.

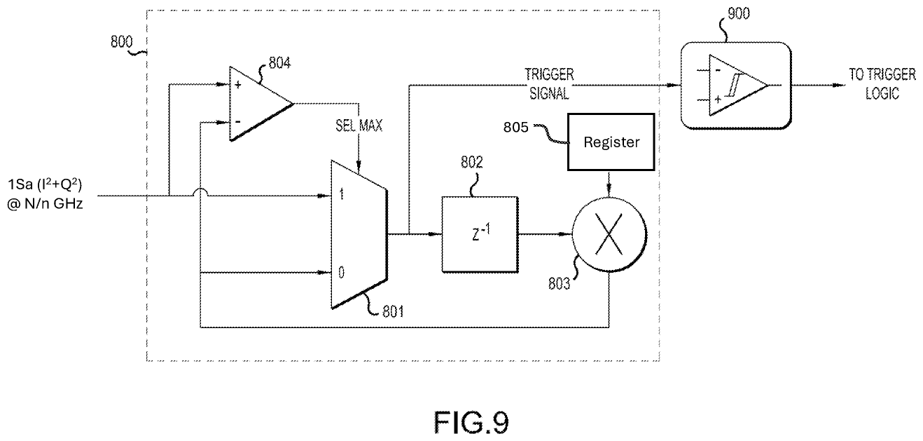

Referring to FIG. 9, an example of a leaky peak detector (LPD) 800 of the of the inventive concepts is illustrated. The LPD 800 is a component of the spectrum analyzer that operates to compare the input power signal to a decayed value stored in a memory element (delay) 802 and select a larger value between the input power signal and the decayed value. The larger value is then forwarded as a trigger signal for further processing.

The LPD 800 includes a comparator 804, a multiplier 803, a multiplexer 801, and a memory element (delay) 802. The comparator 804 is configured to compare the input power signal to the decayed value stored in the memory element 802. The larger value between the input power signal and the decayed value is then selected by the comparator 804.

In some operational variations, the decayed value stored in the memory element 802 is obtained by applying a decay factor to a previously stored value in the memory element 802. This delay factor may be stored, for example, in a register 805 as shown in FIG. 9. This operational variation allows for the decayed value to be dynamically adjusted based on the previously stored value, thereby providing flexibility in processing the input power signal.

In other operational variations, the decay factor applied to the previously stored value in the memory element 802 to obtain the decayed value is programmable. This operational variation provides further flexibility in processing the input power signal, as the decay factor can be adjusted based on specific requirements or conditions.

The larger value selected by the comparator 804 is then forwarded as a trigger signal to a hysteresis comparator 900 for triggering. The hysteresis comparator 900 is configured to receive the trigger signal and generate a trigger event based on the trigger signal. This functional variation allows for the trigger signal to be used for triggering specific events or changes in the signal, such as the start of a transmission.

In some configuration variations, the output of the multiplexer 801 is fed to the next block in the chain, and the first one in the chain is fed by the value from the previous clock cycle. This configuration variation allows for the input power signal to be processed in a sequential manner, thereby providing efficient processing of the input power signal.

In other configuration variations, the circuit is implemented as a programmable shift division instead of a multiplier for faster operation in hardware. This configuration variation allows for the circuit to operate at a higher speed, thereby improving the overall performance of the spectrum analyzer 500.

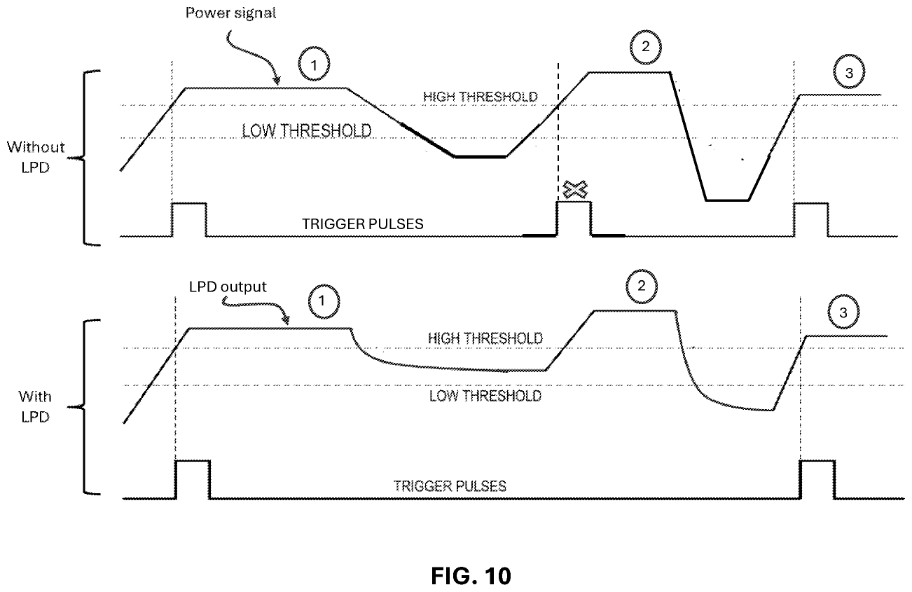

Referring to FIG. 10, an example is presented comparing the generation of trigger pulses without benefit of the LPD 800 and with implementation of the LPD 800. It will be understood that the waveforms presented in these figures are for explanatory purposes only and may not be an exact representation.

The top of FIG. 10 represents the case where no LPD 800 is provided between the output of the FST 300 and the input of the hysteresis comparator 900. In this case, the output of the FST 300 (the power signal in FIG. 10) is subject to hysteresis comparison. In this example, the comparator 900 is set or becomes active when the power signal falls in the negative direction below a lower threshold. Once set, the comparator 900 is triggered and an output pulse is generated when the power signal rises in the positive direction to an upper threshold. This is merely an example, however, and other comparison schemes are possible. As another example, the comparator can be set when power signal rises above the high threshold, and then trigger a pulse when the power signal falls below the lower threshold.

In the example of FIG. 10, the power signal is shown as have three positive transitions above the high threshold. The positive transitions are labelled circle-1, circle-2 and circle-3 in the figure. The first and third positive transitions (circle-1 and circle-3) denote starts of data transmissions which properly result in a trigger pulse at the output of the comparator 900. The middle transition (circle-2), however, is an errant interim high power transition resulting in an errant trigger pulse (marked X in FIG. 10). This is because the power signal, after the first transition (circle-1), drops below the lower threshold, thereby setting (or arming) the comparator 900. In this set state, the errant pulse is generated when the power signal crosses the high threshold during its ascent to the second positive transition (circle-2).

Turning now to the lower half of FIG. 10, the corresponding output signal of the LPD 800 is shown. That is, as described previously, the LPD 800 compares the input power signal to a decayed value stored in a memory element. The larger value between the input power signal and the decayed value is then selected and forwarded as a trigger signal.

As a result, the rising slopes of the LPD 800 output is determined by the speed at which the power signal increases. The flat horizontal sections occur where the power is constant (or nearly constant but flattened by the leaking time constant). In other words, the rising and flat sections of the LPD 800 output signal essentially mirror the behavior of the power signal.

On the other hand, the negative slopes of the output signal of the LPD 800 are determined by the slower of (1) the power signal decay, or (2) the leaky peak detector decay. In the example of FIG. 10, the leaky peak detector decay is slower than the power signal decay (shown in the top of FIG. 10). As such, the negative slopes of the output signal of the LPD 800 decay at a slower rate than those of the power signal. In the case of the negative slope immediately following the first positive transition (circle-1), the signal magnitude is prevented from dropping below the low threshold. As such, the comparator 900 is not set or armed, and therefore no trigger pulse is generated when the output signal of the LPD 800 increases above the high threshold enroute to the second positive transition (circle-2).

In this way, the LPD 800 and hysteresis comparator 900 can effectively prevent undesired triggers caused by errant power transitions in the input power signal. By applying a slow decay to the power transitions and using a hysteresis comparator with a low and high hysteresis band, the LPD 800 and hysteresis comparator 900 can ensure that the data of interest is acquired and that undesired triggers are effectively filtered out.

Variations of the operations described above will be apparent to those skilled in the art. For example, in the example of FIG. 10, the input power signal has a high level at given transmission intervals of the input digital signal. However, the input power signal may instead have a low level at the given transmission intervals of the input digital signal. In this case, in some embodiments, the hysteresis comparator 900 may be set (or armed) when the input power signal exceeds the upper threshold, and then triggered to output a pulse when the input power signal falls below the lower threshold. That is, instead of larger of the input power signal and the decayed value being selected the LPD 800, the lesser of input power signal and the decayed value would be selected.

As another example, in the embodiments described above, the decayed value is obtained by multiplying the output of the multiplexer (i.e., either the power signal or a previous decayed value) by a decay factor. However, the inventive concepts are not limited in this manner. For example, the decay value may be obtained by subtracting a fixed value from the multiplexer output, with clipping at 0 to prevent the signal from going negative. In this case, the multiplier would be replaced with a subtractor and a limiter.

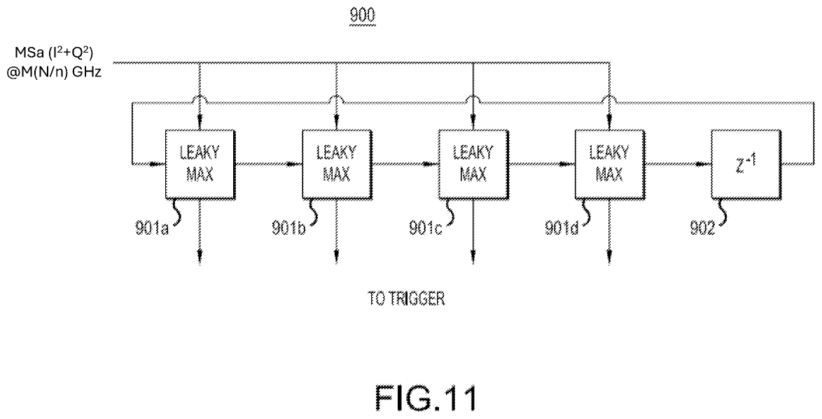

Referring to FIG. 11, an example of a polyphase peak detector is illustrated. The polyphase peak detector includes multiple leaky peak detectors (LPD) 901a, 901b, 901c, and 901d, and a memory element (delay) 902. Here, the LPDs are daisy chained in order to produce a polyphase version of the design. Each phase of the peak detector forwards its signal with the decay factor applied to the next phase. The final phase (LPD 901d) stores its decayed value in the memory element 902 which is read by the first phase (LPD 901a) the following clock cycle. Each LPD 901a, 901b, 901c, and 901d may be configured as in FIG. 9, except that the memory element 802 shown in FIG. 9 may be omitted.

In some operational variations, due to processing limitations, the circuit processes multiple samples in parallel. This operational variation allows for efficient processing of the input power signal, as multiple samples can be processed simultaneously. This can be particularly useful when the input power signal contains a large number of samples that would otherwise take a long time to process sequentially.

Each LPD in the polyphase peak detector operates in parallel with the other LPDs. This means that each LPD can process a different sample of the input power signal at the same time as the other LPDs. This parallel processing capability allows the polyphase peak detector to process multiple (M in FIG. 11) samples of the input power signal within a single clock cycle, thereby improving the overall performance of the spectrum analyzer. As one non-limiting example, M may equal 10. The resultant output signals can then be sent to a regular edge detection circuit with hysteresis for triggering, achieving the required time decay effect.

While the invention has been illustrated and described in detail in the drawings and foregoing description, such illustration and description are to be considered illustrative or exemplary and not restrictive; the invention is not limited to the disclosed embodiments. Other variations to the disclosed embodiments can be understood and effected by those skilled in the art in practicing the claimed invention, from a study of the drawings, the disclosure, and the appended claims. While representative embodiments are disclosed herein, one of ordinary skill in the art will appreciate that many variations that are in accordance with the present teachings are possible and remain within the scope of the appended claim set. The invention therefore is not to be restricted except within the scope of the appended claims.

What is claimed is:

1. A spectrum analyzer triggering system, comprising:
a frequency select trigger (FST) configured to generate a power signal from an input digital signal, the input power signal having high or low levels at given transmission intervals of the input digital signal;
a hysteresis comparator configured to generate a trigger pulse at rising or falling edges of the input power signal; and
a leaky peak detector (LPD) configured to inhibit errant rising or falling edges of the input power signal from causing the hysteresis comparator to generate a trigger pulse.

2. The spectrum analyzer triggering system of claim 1, wherein the digital signal is a complex IQ signal, and the power signal is generated having a magnitude I²+Q².

3. The spectrum analyzer triggering system of claim 1, wherein the LPD comprises:
a comparator configured to compare the input power signal with a current decayed value,
a multiplexer, under control of the comparator, configured to output one of the input power signal and the current decayed value as a trigger signal; and
a memory unit configured to store the trigger signal for use in a subsequent operation to determine a next decayed value.

4. The spectrum analyzer triggering system of claim 3, wherein the input power signal has a high level at the given transmission intervals of the input digital signal, and the multiplexer outputs a greater of the input power signal and the current decayed value as the trigger signal.

5. The spectrum analyzer triggering system of claim 3, wherein the input power signal has a low level at the given transmission intervals of the input digital signal, and the multiplexer outputs a lesser of the input power signal and the current decayed value as the trigger signal.

6. The spectrum analyzer triggering system of claim 3, wherein the LPD further comprises a multiplier configured to multiply the trigger signal stored in the memory unit and a decay factor to obtain the next decayed value.

7. The spectrum analyzer triggering system of claim 6, further comprising a register for storing the decay value.

8. The spectrum analyzer triggering system of claim 7, wherein the decay factor is programmable.

9. The spectrum analyzer triggering system of claim 1, wherein the input power signal is supplied at a rate of one sample per clock, and the LPD processes the input power signal at a rate of one sample per clock.

10. A polyphase peak detector, comprising:
a memory element; and
a plurality of leaky peak detectors (LPDs) connected in a daisy chain, the plurality of leaky peak detectors including a first LPD of the daisy chain and a last LPD of the daisy chain, each LPD receiving an input power signal of M samples per clock, where M is a plural integer,
wherein each LPD is configured, during each clock, to compare a respective sample of the input power signal with a decayed value, and to output a selected one of the input power signal and the decayed value as a trigger signal,
wherein, except for the last LPD of the daisy chain, the decayed value of each LPD of the daisy chain is forwarded to each next LPD of the daisy chain for processing, and
wherein the last LPD of the daisy chain forwards its decayed value to the memory element for storage therein, and the first LPD of the daisy chain receives the decayed value stored in the memory element.

11. The polyphase peak detector of claim 10, wherein the decayed value of a given clock in each LPD is obtained by applying a decay factor to the trigger signal of a previous clock.

12. The polyphase peak detector of claim 11, further comprising a register for storing the decay value.

13. The polyphase peak detector of claim 12, wherein the decay factor is programmable.

14. The polyphase peak detector of claim 10, wherein the input power signal is derived from a complex IQ signal.

15. The polyphase peak detector of claim 10, wherein the trigger signals of the LPDs are forwarded to an edge detection circuit with hysteresis for triggering.
